(19) United States
(12) Patent Application Publication
(10) Pub. No.: US 2019/0287445 A1
(43) Pub. Date: Sep. 19, 2019

(54) ARRAY SUBSTRATE AND DISPLAY PANEL

(71) Applicants: BOE TECHNOLOGY GROUP CO., LTD., Beijing (CN); ORDOS YUANSHENG OPTOELECTRONICS CO., LTD., Ordos, CT (US)

(72) Inventors: Yun Qiao, Beijing (CN); Zhen Wang, Beijing (CN); Zhengkui Wang, Beijing (CN); Han Zhang, Beijing (CN); Jian Sun, Beijing (CN); Xiaozhou Zhan, Beijing (CN); Fei Huang, Beijing (CN); Wenwen Qin, Beijing (CN); Jianjun Zhang, Beijing (CN)

(21) Appl. No.: 16/059,755

(22) Filed: Aug. 9, 2018

(30) Foreign Application Priority Data
Mar. 14, 2018 (CN) 201810209743.8

(51) Int. Cl. G09G 3/20; H01L 27/12

(52) U.S. Cl. CPC G09G 3/20; G09G 2310/0264; H01L 27/124; H01L 27/1218

(57) ABSTRACT

An array substrate and a display panel are provided. The array substrate includes a base substrate having a notch, the base substrate comprising a first region and a second region on opposite sides of the notch; a plurality of gate lines disposed on the base substrate and configured to respectively drive a plurality of rows of pixels on the base substrate, each of the plurality of gate lines being interrupted by the notch into a first gate sub-line in the first region and a second gate sub-line in the second region; and a gate driving device in the first region and/or the second region, the gate driving device is configured such that the first gate sub-line and the second gate sub-line of each of the plurality of gate lines are simultaneously scanned.

### CROSS-REFERENCE TO RELATED APPLICATION

This application claims priority to Chinese Patent Application No. 201810209743.8 filed on Mar. 14, 2018 in the State Intellectual Property Office of China, the disclosure of which is hereby incorporated by reference in its entirety.

### BACKGROUND

### Technical Field

The present disclosure relates to the field of display technologies, and in particular, to an array substrate and a display panel.

### Description of Related Art

Generally, in a rectangular panel in the related art a gate driving circuit is placed on the left and right sides of its frame, and devices such as switches for electrical testing are placed on the top side of the frame.

However, a full-screen mobile phone with an irregular-shaped screen is in the mainstream of mobile phones. In the irregular-shaped screen design, it is important to route wirings at irregular regions in the irregular-shaped screen and reduce a bezel size at the irregular regions.

### SUMMARY

An embodiment of the present disclosure provides an array substrate comprising: a base substrate having a notch, the base substrate comprising a first region and a second region on opposite sides of the notch; a plurality of gate lines disposed on the base substrate and configured to respectively drive a plurality of rows of pixels on the base substrate, wherein each of the plurality of gate lines is interrupted by the notch into a first gate sub-line in the first region and a second gate sub-line in the second region; and a gate driving device in the first region and/or the second region, wherein the gate driving device is configured such that the first gate sub-line and the second gate sub-line of each of the plurality of gate lines are simultaneously scanned.

In some embodiments, the array substrate further comprising: a plurality of lead wires at an edge of the base substrate surrounding the notch, wherein each of the lead wires connects the first gate sub-line to the second gate sub-line of one of the gate lines electrically.

In some embodiments, the first gate sub-line of each of the plurality of gate lines comprises a first end away from the notch and a second end adjacent to the notch, and the second gate sub-line of each of the plurality of gate lines comprises a first end away from the notch and a second end adjacent to the notch, each of the lead wires electrically connects the second end of the first gate sub-line to the second end of the second gate sub-line of one of the plurality of gate lines.

In some embodiments, the gate driving device comprises: a first gate driving circuit group at an edge of the first region opposite to the notch, wherein a plurality of gate driving circuits in the first gate driving circuit group are respectively electrically connected to the first ends of the first gate sub-lines of a plurality of gate lines in odd-numbered rows to provide scanning signals to the plurality of gate lines in odd-numbered rows; and a second gate driving circuit group at an edge of the second region opposite to the notch, wherein a plurality of gate driving circuits in the second gate driving circuit group are respectively electrically connected to the first ends of the second gate sub-lines of a plurality of gate lines in even-numbered rows to provide scanning signals to the plurality of gate lines in even-numbered rows.

In some embodiments, the first gate sub-line of each of the plurality of gate lines comprises a first end away from the notch and a second end adjacent to the notch, and the second gate sub-line of each of the plurality of gate lines comprises a first end away from the notch and a second end adjacent to the notch, and wherein the gate driving device comprises: a first gate driving circuit group at an edge of the first region opposite to the notch, wherein a plurality of gate driving circuits in the first gate driving circuit group are respectively electrically connected to the first ends of the first gate sub-lines of a plurality of gate lines in odd-numbered rows to provide scanning signals to the first gate sub-lines of the plurality of gate lines in odd-numbered rows; a second gate driving circuit group at an edge of the second region opposite to the notch, wherein a plurality of gate driving circuits in the second gate driving circuit group are respectively electrically connected to the first ends of the second gate sub-lines of a plurality of gate lines in even-numbered rows to provide scanning signals to the second gate sub-lines of the plurality of gate lines in even-numbered rows; a third gate driving circuit group at an edge of the second region adjacent to the notch, wherein a plurality of gate driving circuits in the third gate driving circuit group are respectively electrically connected to the second ends of the second gate sub-lines of the plurality of gate lines in odd-numbered rows to provide scanning signals to the second gate sub-lines of the plurality of gate lines in odd-numbered rows; and a fourth gate driving circuit group at an edge of the first region adjacent to the notch, wherein a plurality of gate driving circuits in the fourth gate driving circuit group are respectively electrically connected to the second ends of the first gate sub-lines of the plurality of gate lines in even-numbered rows to provide scanning signals to the first gate sub-lines of the plurality of gate lines in even-numbered rows.

In some embodiments, the first gate driving circuit group and the third gate driving circuit group have the same structure, and the second gate driving circuit group and the fourth gate driving circuit group have the same structure.

In some embodiments, the first gate driving circuit group and the third gate driving circuit group simultaneously output the same scanning signals, and the second gate driving circuit group and the fourth gate driving circuit group simultaneously output the same scanning signals.

In some embodiments, the first gate sub-line of each of the plurality of gate lines comprises a first end away from the notch and a second end adjacent to the notch, and the second gate sub-line of each of the plurality of gate lines comprises a first end away from the notch and a second end adjacent to the notch, and wherein the gate driving device comprises: a fifth gate driving circuit group at an edge of the first region opposite to the notch, wherein a plurality of gate driving circuits in the fifth gate driving circuit group are respectively electrically connected to the first ends of the first gate sub-lines of the plurality of gate lines to provide scanning signals to the first gate sub-lines of the plurality of gate lines; and a sixth gate driving circuit group at an edge of the second region opposite to the notch, wherein a plurality of gate driving circuits in the sixth gate driving circuit group are respectively electrically connected to the first ends of the second gate sub-lines of the plurality of gate lines to provide scanning signals to the second gate sub-lines of the plurality of gate lines.

In some embodiments, the fifth gate driving circuit group and the sixth gate driving circuit group simultaneously output the same scanning signals.

In some embodiments, the notch comprises a U-shaped notch, a V-shaped notch, or an arc-shaped notch.

In some embodiments, the gate driving device sequentially scans the plurality of gate lines in a direction from a top to a bottom of the notch.

An embodiment of the present disclosure provides a display panel comprising the array substrate of any one of the above embodiments.

### BRIEF DESCRIPTION OF THE DRAWINGS

The drawings are used to provide a further understanding of technical solutions of the present disclosure. The drawings are used together with the embodiments of the present disclosure to explain the technical solutions of the present disclosure, and the drawings do not limit the technical solutions of the present disclosure.

FIG. 1 is a schematic structural view of an array substrate according to an embodiment of the present disclosure;

FIG. 2 is a schematic structural view of an arrangement of gate lines of an array substrate according to an embodiment of the present disclosure;

FIG. 3 is a schematic structural view of an array substrate according to an embodiment of the present disclosure;

FIG. 4 is a schematic structural view of an arrangement of gate lines of an array substrate according to an embodiment of the present disclosure;

FIG. 5 is a schematic structural view of an array substrate according to an embodiment of the present disclosure; and

FIG. 6 is a schematic structural view of an arrangement of gate lines of an array substrate according to an embodiment of the present disclosure.

### DETAILED DESCRIPTION OF EMBODIMENTS

Embodiments of the present disclosure will be described in detail below with reference to the accompanying drawings. It should be noted that in case that the embodiments do not conflict with each other, the embodiments in the present disclosure and the features in the embodiments may be combined with each other.

The present disclosure provides an array substrate including a base substrate. A plurality of gate lines and a plurality of gate driving circuits are disposed on the base substrate, and the base substrate is further provided with a notch. The base substrate includes a first region and a second region on opposite sides of the notch, the plurality of gate lines are interrupted by the notch into a plurality of first gate sub-lines located in the first region and a plurality of second gate sub-lines located in the second region.

The first gate sub-line and the second gate sub-line of the same gate line on the array substrate need to receive the same gate driving signal (i.e. scanning signal), thereby effectively ensuring normal display of the display panel including the array substrate. While satisfying the normal display of the display panel, it is necessary to design a wiring scheme at the edge of the base substrate adjacent to the notch, so that a bezel of the array substrate adjacent to notch is as narrow as possible, thereby satisfying narrow bezel requirements of full screen.

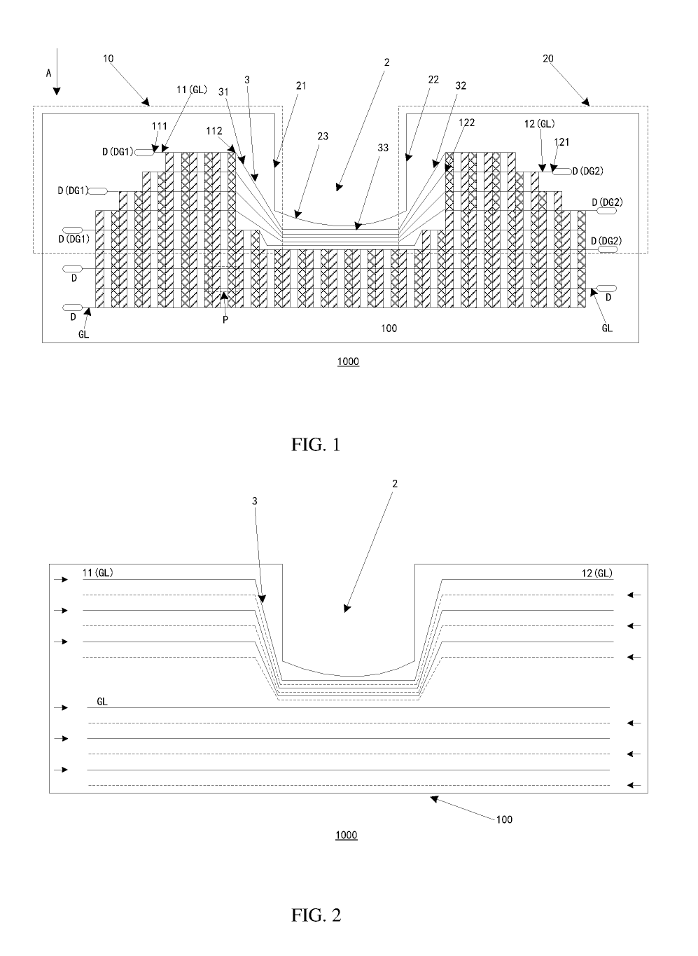

FIG. 1 is a schematic structural view of an array substrate according to an embodiment of the present disclosure. FIG. 2 is a schematic structural view of an arrangement of gate lines of an array substrate according to an embodiment of the present disclosure. As shown in FIG. 1 and FIG. 2, an array substrate 1000 provided by an embodiment of the present disclosure includes a base substrate 100. The base substrate 100 is provided with a notch 2 so that the base substrate 100 has an irregular shape. A plurality of pixels P are provided on the base substrate100 in an array. In an embodiment, each pixel P includes three sub-pixels for displaying three colors, such as red, green, and blue, respectively. A plurality of gate lines GL are electrically connected to the plurality of pixel rows, respectively, that is, one gate line is connected to each of pixels P in one pixel row. A part of the plurality of pixel rows and the gate lines GL corresponding to the part of the plurality of pixel rows are interrupted by the notch 2. The base substrate 100 includes a first region 10 and a second region 20 on opposite sides of the notch 2. Each interrupted pixel row includes a first sub-pixel row located in the first region 10 and a second sub-pixel row located in the second region 20, and correspondingly, each interrupted gate line GL includes a first gate sub-line 11 located in the first region 10 and a second gate sub-line 12 located in the second region 20.

The array substrate 1000 further includes a plurality of lead wires 3 disposed on the base substrate 100, each lead wire 3 is electrically connected with the first gate sub-line 11 and the second gate sub-line 12 of one interrupted gate line GL such that the first gate sub-line 11 and the second gate sub-line 12 of each interrupted gate line may simultaneously receive the same gate driving signal.

In the embodiment, the plurality of lead wires 3 are disposed at an edge of the base substrate surrounding the notch 2. Specifically, the notch 2 is a through notch 2, and the notch 2 interrupts a part of the plurality of pixel rows and the gate lines GL corresponding to the part of the plurality of pixel rows. The shape of the lead wires 3 is adapted to the shape of the notch 2, and the lead wires 3 are disposed around and adjacent to the notch 2. As shown in FIG. 1, the notch 2 includes a first side wall 21 and a second side wall 22 opposite to each other, and a bottom wall 23. Each of the lead wires 3 includes a first portion 31 disposed adjacent to the first side wall 21 of the notch 2, a second portion 32 disposed adjacent to the second side wall 21 of the notch 2 and a third portion 33 disposed adjacent to the bottom wall 23 of the notch 2. The plurality of lead wires 3 may not only make the first gate sub-line 11 and the second gate sub-line 12 of the same gate line at both sides of the notch 2 receive the same gate driving signal, but also effectively reduce the occupation space of the plurality of lead wires 3 on the base substrate 100. Therefore, a narrow bezel may be realized at the edge of the base substrate 100 surrounding the notch 2.

In an embodiment, the first gate sub-line 11 of each of the interrupted gate lines GL located in the first region 10 has a first end 111 and a second end 112. The first end 111 is located at an edge of the first region 10 of the base substrate 100 away from the notch 2, such as at a left edge of the first region 10 shown in FIG. 1. The second end 112 is located at an edge of the first region 10 of the base substrate 100 adjacent to the notch 2, such as at a right edge of the first region 10 shown in FIG. 1. The second gate sub-line 11 of each of the interrupted gate lines GL located in the second region 20 also has a first end 121 and a second end 122. The first end 121 is located at an edge of the second region 20 of the base substrate 100 away from the notch 2, such as at a right edge of the second region 20 shown in FIG. 1. The second end 122 is located at an edge of the second region 20 of the base substrate 100 adjacent to the notch 2, such as at a left edge of the second region 20 shown in FIG. 1. An end of each lead wire 3 may be directly electrically connected to the second end 112 of the corresponding first gate sub-line 11, and the other end of each lead wire 3 may be directly electrically connected to the second end 122 of the corresponding second gate sub-line 12 so that the first gate sub-line 11 and the second gate sub-line 11 of each interrupted gate line GL are conductively connected with each other.

As shown in FIG. 1, the array substrate 1000 further includes a gate driving device disposed on the base substrate for driving the plurality of gate lines. The gate driving device includes a plurality of gate driving circuits D disposed on two opposite edges of the base substrate 100, for example, left and right edges of the base substrate 100 as shown in FIG. 1. A plurality of gate driving circuits D located at the left edge of the base substrate 100 are electrically connected to left ends of the gate lines GL in odd-numbered rows, respectively, that is, the gate lines GL in odd-numbered rows are driven by the plurality of gate driving circuits D located at the left edge of the base substrate 100. A plurality of gate driving circuits D located on the right edge of the base substrate 100 are electrically connected to right ends of the gate lines GL in even-numbered rows, respectively, that is, the gate lines GL in even-numbered rows are driven by the plurality of gate driving circuits D located at the right edge of the base substrate 100. The plurality of gate driving circuits D located in the first region 10 constitute a first gate driving circuit group DG1, and the first gate driving circuit group DG1 is disposed on the edge of the first region 10 opposite to the notch 2. The plurality of gate driving circuits D in the first gate driving circuit group DG1 are electrically connected to the first ends 111 of first gate sub-lines 11 of the plurality of interrupted gate lines in odd-numbered rows, respectively. In FIG. 2, solid lines represent the gate lines GL in odd-numbered rows, and dotted lines represent the gate lines GL in even-numbered rows. As shown in FIG. 2, a driving signal provided by each gate driving circuit D in the first gate driving circuit group DG1 may be firstly transmitted to the first gate sub-line 11 of the corresponding interrupted gate line, and then transmitted to the corresponding second gate sub-line 12 through the lead wire 3 electrically connected to the first gate sub-line 11, so as to scan the interrupted gate line. The plurality of gate driving circuits D located in the second region 20 constitute a second gate driving circuit group DG2, and the second gate driving circuit group DG2 is disposed at the edge of the second region 10 opposite to the notch 2. The plurality of gate driving circuits D in the second gate driving circuit group DG2 are electrically connected to the first ends 121 of second gate sub-lines 12 of the plurality of interrupted gate lines in even-numbered rows, respectively. As shown in FIG. 2, a driving signal provided by each gate driving circuit D in the second gate driving circuit group DG2 may be firstly transmitted to the second gate sub-line 12 of the corresponding interrupted gate line, and then transmitted to the corresponding first gate sub-line 11 through the lead wire 3 electrically connected to the second gate sub-line 12, so as to scan the interrupted gate line.

In an embodiment, the plurality of gate lines GL are sequentially scanned by the gate driving device in the direction A in FIG. 1. In other embodiments, the plurality of gate lines may be scanned by the gate driving device in other scanning manners.

In an embodiment, the notch 2 may be a U-shaped notch, a V-shaped notch, or an arc-shaped notch, etc., which is not specifically limited herein.

Specifically, the shape of the notch 2 may be selected according to actual conditions. For example, as shown in FIG. 1, the notch 2 is a U-shaped notch, and the U-shaped notch includes two opposite side walls, that is, the first side wall 21 and the second side wall 22, and a curved bottom wall, the two side walls are disposed perpendicular to the plurality of gate lines.

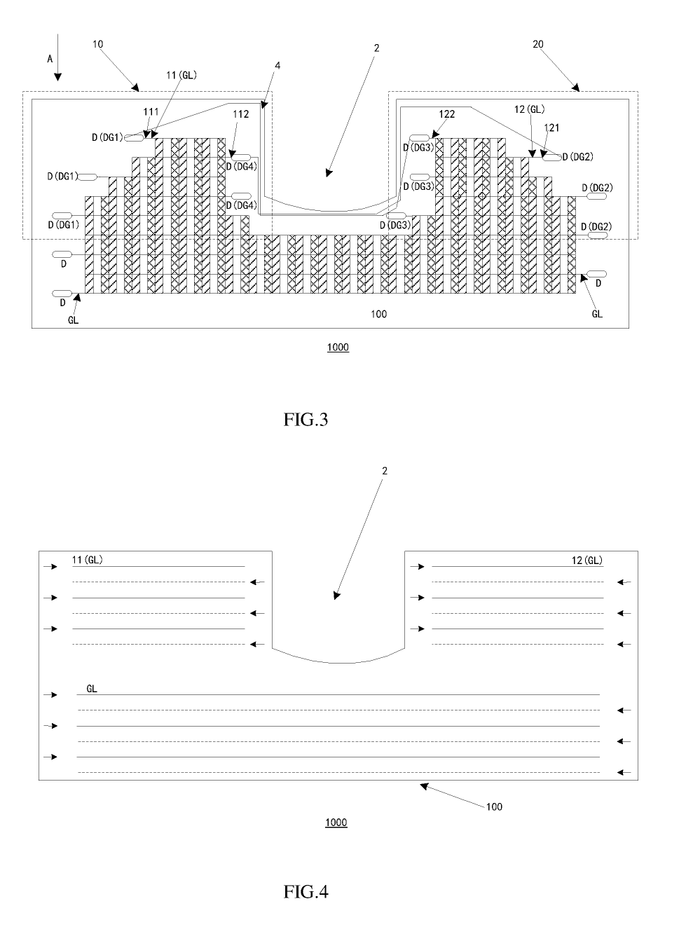

FIG.3 is a schematic structural view of an array substrate according to an embodiment of the present disclosure, and FIG. 4 is a schematic structural view of an arrangement of gate lines of an array substrate according to an embodiment of the present disclosure. As shown in FIG. 3 and FIG. 4, an embodiment of the present disclosure provides an array substrate 1000. A structure of the array substrate 1000 is similar to that of the array substrate in the previous embodiment, except that there is no lead wire in the embodiment, and the first gate sub-line 11 in the first region 10 and the corresponding second gate sub-line 12 in the second region 20 of each interrupted gate line GL are not physically electrically connected.

Similar to the previous embodiment, as shown in FIG. 3, the array substrate 1000 in the embodiment also includes a gate driving device for driving a plurality of gate lines disposed on the base substrate 100. In the embodiment, the gate driving device includes a plurality of gate driving circuits D disposed at two opposite edges of the base substrate 100, for example, left and right edges of the base substrate 100 as shown in FIG. 3, and two opposite sides of the base substrate adjacent to the notch 2. A plurality of gate driving circuits D located at the left edge of the base substrate 100 are electrically connected to the left ends of the gate lines in odd-numbered rows, respectively, and a plurality of gate driving circuits D located on the right edge of the base substrate 100 are electrically connected to the right ends of the gate lines in even-numbered rows. The plurality of gate driving circuits D located at the edge of the first region 10 opposite to the notch 2 constitute a first gate driving circuit group DG1. The plurality of gate driving circuits D in the first gate driving circuit group DG1 are connected with first ends 111 of first gate sub-lines 11 of the plurality of interrupted gate lines in odd-numbered rows, respectively. The plurality of gate driving circuits D at the edge of the second region 20 opposite to the notch 2 constitute a second gate driving circuit group DG2. The plurality of gate driving circuits D in the second gate driving circuit group DG2 are connected with first ends 121 of second gate sub-lines 12 of the plurality of interrupted gate lines in even-numbered rows, respectively. The plurality of gate driving circuits D located at the edge of the second region 20 adjacent to the notch 2 constitute a third gate driving circuit group DG3. The plurality of gate driving circuits D in the third gate driving circuit group DG3 are connected with second ends 122 of second gate sub-lines 12 of the plurality of interrupted gate lines in odd-numbered rows, respectively. The plurality of gate driving circuits D located at the edge of the first region 10 adjacent to the notch 2 constitute a fourth gate driving circuit group DG4. The plurality of gate driving circuits D in the fourth gate driving circuit group DG4 are connected with second ends 112 of first gate sub-lines 11 of the plurality of interrupted gate lines in even-numbered rows, respectively.

In FIG. 4, solid lines represent the gate lines GL in odd-numbered rows, and dotted lines represent the gate lines GL in even-numbered rows. As shown in FIG. 4, for the plurality of first gate sub-lines 11 located in the first region 10, the first gate sub-lines in odd-numbered rows are respectively driven by the plurality of gate driving circuits D of the first gate driving circuit group DG1. The gate driving signal output by each of the gate driving circuits D of the first gate driving circuit group DG1 is transmitted from the first end 111 of the first gate sub-line 11 in corresponding odd-numbered row to the second end 112 of the first gate sub-line 11 in corresponding odd-numbered row. The first gate sub-lines in even-numbered rows are respectively driven by the plurality of gate driving circuits of the fourth gate driving circuit group DG4. The gate driving signal output by each of the gate driving circuits D of the fourth gate driving circuit group DG4 is transmitted from the second end 112 of the first gate sub-line 11 in corresponding even-numbered row to the first end 111 of the first gate sub-line 11 in corresponding even-numbered row.

For the plurality of second gate sub-lines 12 located in the second region 20, the second gate sub-lines in odd-numbered rows are respectively driven by the plurality of gate driving circuits D of the third gate driving circuit group DG3. The gate driving signal output by each of the gate driving circuits D of the third gate driving circuit group DG3 is transmitted from the second end 122 of the second gate sub-line 12 in corresponding odd-numbered row to the first end 121 of the second gate sub-line 12 in corresponding odd-numbered row. The second gate sub-lines in even-numbered rows are respectively driven by the plurality of gate driving circuits D of the second gate driving circuit group DG2. The gate driving signal output by each of the gate driving circuits D of the second gate driving circuit group DG2 is transmitted from the first end 121 of the second gate sub-line 12 in corresponding even-numbered row to the second end 122 of the second gate sub-line 12 in corresponding even-numbered row.

In this embodiment, as shown in FIG. 3, a structure of the first gate driving circuit group DG1 is completely the same as that of the third gate driving circuit group DG3. The first gate driving circuit group DG1 and the third gate driving circuit group DG3 are connected by connection lines 4, so as to access the same control signals and cascade signals. Specifically, a starting scan gate driving circuit of the first gate driving circuit group DG1 and a starting scan gate driving circuit of the third gate driving circuit group DG3 are connected by a connection line 4, and an ending scan gate driving circuit of the first gate driving circuit group DG1 and an ending scan gate driving circuit of the third gate driving circuit group DG3 are connected by another connection line 4. Therefore, the first gate driving circuit group DG1 and the third gate driving circuit group DG3 simultaneously output the same gate driving signals, for example, timing charts of the gate driving signals are identical, so that the first gate sub-line 11 and the second gate sub-line 12 of each interrupted gate line GL in odd-numbered row may be scanned simultaneously. A structure of the second gate driving circuit group DG2 is completely the same as that of the fourth gate driving circuit group DG3. The second gate driving circuit group DG2 and the fourth gate driving circuit group DG4 are connected by connection lines 4, so as to access the same control signals and cascade signals. Specifically, a starting scan gate driving circuit of the second gate driving circuit group DG2 and a starting scan gate driving circuit of the fourth gate driving circuit group DG4 are connected by a connection line 4, and an ending scan gate driving circuit of the second gate driving circuit group DG2 and an ending scan gate driving circuit of the fourth gate driving circuit group DG4 are connected by another connection line 4. Therefore, the second gate driving circuit group DG2 and the fourth gate driving circuit group DG4 simultaneously output the same gate driving signals, for example, timing charts of the gate driving signals are identical, the first gate sub-line 11 and the second gate sub-line 12 of each interrupted gate line GL in even-numbered row may be scanned simultaneously.

In this embodiment, the amount of connection lines is significantly reduced relative to the amount of lead wires in the previous embodiment, for example, only four connection lines, and only two connection lines are shown in FIG. 3, thereby occupying less space on the base substrate 100. Therefore, a narrow bezel is achieved at the edge of the base substrate 100 surrounding the notch 2.

In an embodiment, the plurality of gate lines GL are sequentially scanned by the gate driving device in the direction A in FIG. 3. In other embodiments, the plurality of gate lines GL may be scanned by the gate driving device in other scanning manners.

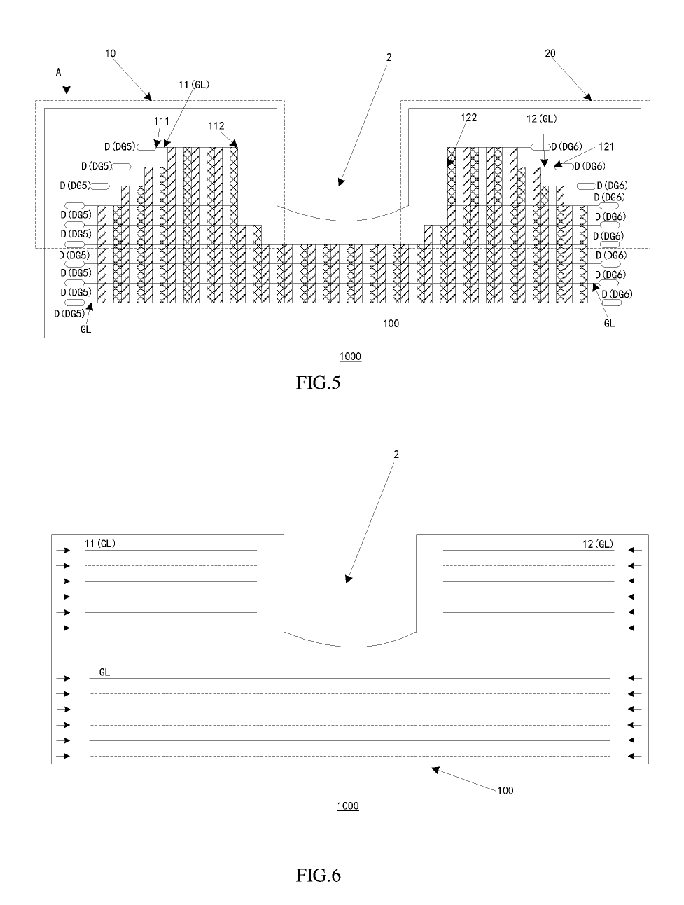

FIG. 5 is a schematic structural view of an array substrate according to an embodiment of the present disclosure, and FIG. 6 is a schematic structural view of an arrangement of gate lines of an array substrate according to an embodiment of the present disclosure. As shown in FIG. 5 and FIG. 6, an embodiment of the present disclosure provides an array substrate 1000. A structure of the array substrate 1000 is similar to structures of the array substrates in the previous embodiments, except that there is no lead wire in the embodiment, and the first gate sub-line 11 in the first region 10 and the corresponding second gate sub-line 12 in the second region 20 of each interrupted gate line GL are not physically electrically connected, further there is no connection line in this embodiment.

As shown in FIG. 5, the array substrate 1000 includes a gate driving device for driving a plurality of gate lines disposed on the substrate. The gate driving device includes a plurality of gate driving circuits D disposed at two opposite edges of the base substrate 100, for example, left and right edges of the base substrate 100 as shown in FIG. 5. A plurality of gate driving circuits D located at the left edge of the base substrate 100 constitute a fifth gate driving circuit group DG5 and are electrically connected to the left ends of all the gate lines GL. A plurality of gate driving circuits D located on the right edge of the base substrate 100 constitute a sixth gate driving circuit group DG6 and are electrically connected to the right ends of all the gate lines GL. Thus, the first ends 111 of the plurality of first gate sub-lines 11 located in the first region 10 are connected to the respective gate driving circuits D of the fifth gate driving circuit group DG5, and the first ends 121 of the plurality of second gate sub-lines 12 located in the second region 10 are connected to the respective gate driving circuits D of the sixth gate driving circuit group DG6. In FIG. 6, solid lines represent the gate lines GL in odd-numbered rows, and dotted lines represent the gate lines GL in even-numbered rows. As shown in FIG. 6, for each interrupted gate line GL, the first gate sub-line 11 thereof located in the first region 10 is driven by the fifth gate driving circuit group DG5, and the second gate sub-line 12 thereof located in the second region 20 is driven by the sixth gate driving circuit group DG6. For each of gate lines GL which are not interrupted, it is simultaneously scanned from the left and right ends by the fifth gate driving circuit group DG5 and the sixth gate driving circuit group DG6.

The fifth gate driving circuit group DG5 and the sixth gate driving circuit group DG6 are identical in structure, and they may receive the same external signal so that the first gate sub-line 11 and the second gate sub-line 12 of each interrupted gate line GL may be scanned at the same time.

In this embodiment, it is not necessary to provide lead wires and connection lines, therefore a narrow bezel is achieved at the edge of the base substrate 100 surrounding the notch 2.

In an embodiment, the plurality of gate lines GL are sequentially scanned by the gate driving device in the direction A in FIG. 5. In other embodiments, the plurality of gate lines may be scanned by the gate driving device in other scanning manners.

An embodiment of the present disclosure provides a display panel, the display panel includes the array substrate of any of the foregoing embodiments.

In the description of the present disclosure, the terms “set”, “joined”, “connection”, “fix”, etc. should be understood broadly. For example, “connection” may be a fixed connection, a detachable connection, or an integral connection, it may be a direct connection or an indirect connection through an intermediate media. For those skilled in the art, the specific meanings of the above terms in the present disclosure may be understood on a case-by-case basis.

In the description of the present specification, the description of the terms “one embodiment”, “some embodiment”, “specific embodiments” and the like is intended to mean that a particular feature, structure, material or characteristic described in connection with the embodiment or example is included in at least one embodiment or example of the present disclosure. In the present specification, the schematic representation of the above terms does not necessarily refer to the same embodiment or example. Furthermore, the particular features, structures, materials, or characteristics described may be combined in a suitable manner in any one or more embodiments or examples.

It should be understood by those skilled in the art that the embodiments disclosed in the embodiments of the present disclosure are as described above, but they are merely used to facilitate the understanding of the embodiments of the present disclosure, and are not intended to limit the embodiments of the present disclosure. Any modification and variation in the form and details of the embodiments may be made by those skilled in the art without departing from the spirit and scope of the embodiments of the present disclosure. However, the scope of patent protection of the embodiments of the present disclosure is still subject to the scope defined by the appended claims.

What is claimed is:

1. An array substrate comprising:
a base substrate having a notch, the base substrate comprising a first region and a second region on opposite sides of the notch;
a plurality of gate lines disposed on the base substrate and configured to respectively drive a plurality of rows of pixels on the base substrate, wherein each of the plurality of gate lines is interrupted by the notch into a first gate sub-line in the first region and a second gate sub-line in the second region; and
a gate driving device in the first region and/or the second region,
wherein the gate driving device is configured such that the first gate sub-line and the second gate sub-line of each of the plurality of gate lines are simultaneously scanned.

2. The array substrate according to claim 1, further comprising:
a plurality of lead wires at an edge of the base substrate surrounding the notch,
wherein each of the lead wires connects the first gate sub-line to the second gate sub-line of one of the gate lines electrically.

3. The array substrate according to claim 2, wherein the first gate sub-line of each of the plurality of gate lines comprises a first end away from the notch and a second end adjacent to the notch, the second gate sub-line of each of the plurality of gate lines comprises a first end away from the notch and a second end adjacent to the notch, and each of the lead wires electrically connects the second end of the first gate sub-line to the second end of the second gate sub-line of one of the plurality of gate lines.

4. The array substrate of claim 3, wherein the gate driving device comprises:
a first gate driving circuit group at an edge of the first region opposite to the notch, wherein a plurality of gate driving circuits in the first gate driving circuit group are respectively electrically connected to the first ends of the first gate sub-lines of a plurality of gate lines in odd-numbered rows to provide scanning signals to the plurality of gate lines in odd-numbered rows; and
a second gate driving circuit group at an edge of the second region opposite to the notch, wherein a plurality of gate driving circuits in the second gate driving circuit group are respectively electrically connected to the first ends of the second gate sub-lines of a plurality of gate lines in even-numbered rows to provide scanning signals to the plurality of gate lines in even-numbered rows.

5. The array substrate of claim 1, wherein the first gate sub-line of each of the plurality of gate lines comprises a first end away from the notch and a second end adjacent to the notch, and the second gate sub-line of each of the plurality of gate lines comprises a first end away from the notch and a second end adjacent to the notch, and
wherein the gate driving device comprises:
a first gate driving circuit group at an edge of the first region opposite to the notch, wherein a plurality of gate driving circuits in the first gate driving circuit group are respectively electrically connected to the first ends of the first gate sub-lines of a plurality of gate lines in odd-numbered rows to provide scanning signals to the first gate sub-lines of the plurality of gate lines in odd-numbered rows;
a second gate driving circuit group at an edge of the second region opposite to the notch, wherein a plurality of gate driving circuits in the second gate driving circuit group are respectively electrically connected to the first ends of the second gate sub-lines of a plurality of gate lines in even-numbered rows to provide scanning signals to the second gate sub-lines of the plurality of gate lines in even-numbered rows;
a third gate driving circuit group at an edge of the second region adjacent to the notch, wherein a plurality of gate driving circuits in the third gate driving circuit group are respectively electrically connected to the second ends of the second gate sub-lines of the plurality of gate lines in odd-numbered rows to provide scanning signals to the second gate sub-lines of the plurality of gate lines in odd-numbered rows; and
a fourth gate driving circuit group at an edge of the first region adjacent to the notch, wherein a plurality of gate driving circuits in the fourth gate driving circuit group are respectively electrically connected to the second ends of the first gate sub-lines of the plurality of gate lines in even-numbered rows to provide scanning signals to the first gate sub-lines of the plurality of gate lines in even-numbered rows.

6. The array substrate according to claim 5, wherein the first gate driving circuit group and the third gate driving circuit group have the same structure, and the second gate driving circuit group and the fourth gate driving circuit group have the same structure.

7. The array substrate according to claim 6, wherein the first gate driving circuit group and the third gate driving circuit group simultaneously output the same scanning signals, and the second gate driving circuit group and the fourth gate driving circuit group simultaneously output the same scanning signals.

8. The array substrate of claim 1, wherein the first gate sub-line of each of the plurality of gate lines comprises a first end away from the notch and a second end adjacent to the notch, and the second gate sub-line of each of the plurality of gate lines comprises a first end away from the notch and a second end adjacent to the notch, and
wherein the gate driving device comprises:
a fifth gate driving circuit group at an edge of the first region opposite to the notch, wherein a plurality of gate driving circuits in the fifth gate driving circuit group are respectively electrically connected to the first ends of the first gate sub-lines of the plurality of gate lines to provide scanning signals to the first gate sub-lines of the plurality of gate lines; and
a sixth gate driving circuit group at an edge of the second region opposite to the notch, wherein a plurality of gate driving circuits in the sixth gate driving circuit group are respectively electrically connected to the first ends of the second gate sub-lines of the plurality of gate lines to provide scanning signals to the second gate sub-lines of the plurality of gate lines.

9. The array substrate according to claim 8, wherein the fifth gate driving circuit group and the sixth gate driving circuit group simultaneously output the same scanning signals.

10. The array substrate according to claim 1, wherein the notch comprises a U-shaped notch, a V-shaped notch, or an arc-shaped notch.

11. The array substrate according to claim 1, wherein the gate driving device sequentially scans the plurality of gate lines in a direction from a top to a bottom of the notch.

12. A display panel comprising the array substrate of claim 1.
